(19) United States
(12) Patent Application Publication
(10) Pub. No.: US 2026/0190746 A1
(43) Pub. Date: Jul. 2, 2026

(54) DISPLAY DEVICE

(71) Applicant: LG Display Co., Ltd., Seoul (KR)

(72) Inventors: Hyang Myoung GWON, Paju-si (KR); Ji Hyun JUNG, Paju-si (KR); Ru Da RHE, Paju-si (KR)

(73) Assignee: LG Display Co., Ltd., Seoul (KR)

(21) Appl. No.: 19/436,814

(22) Filed: Dec. 30, 2025

(30) Foreign Application Priority Data
Dec. 30, 2024 (KR) 10-2024-0200344

(51) Int. Cl. H10K 59/40; G06F 3/044; H10K 59/80

(52) U.S. Cl. CPC H10K 59/40; G06F 3/0443; G06F 3/0446; H10K 59/8792

(57) ABSTRACT

A display device can include a substrate, a plurality of pixels disposed on the substrate, an encapsulation portion disposed on the plurality of pixels, a plurality of touch electrodes disposed on the encapsulation portion, and a black matrix disposed on the plurality of touch electrodes. The plurality of touch electrodes can include a plurality of first opening holes that expose each of the plurality of pixels and a second opening hole larger than the plurality of first opening holes.

### CROSS-REFERENCE TO RELATED APPLICATION

This application claims priority to and the benefit of Korean Patent Application No. 10-2024-0200344, filed in the Republic of Korea on Dec. 30, 2024, the disclosure of which is hereby expressly incorporated by reference in its entirety.

### BACKGROUND

### Field of the Invention

The present specification relates to a display device.

### Discussion of the Related Art

In order to provide various functions to a user, a display device recognizes a touch of a user's finger or pen on a display panel and performs input processing based on the recognized touch.

The display device can include a plurality of touch electrodes disposed on the display panel. The display device can drive the plurality of touch electrodes and detect a change in the capacitance which occurs when the user touches the display panel, thereby sensing the user's touch.

In the display device, an area of the touch electrode needs to be increased to increase touch sensing sensitivity, but there can be problems in that the touch electrode is visible from the outside and the size area of the touch electrode can be limited due to a manufacturing process.

### SUMMARY OF THE INVENTION

An object of the present disclosure is directed to providing a display device including a touch electrode with an increased area (e.g., increased size) without being visible from the outside.

An object of the present disclosure is directed to providing a display device in which an area of the touch electrode is adjustable depending on vacuum equipment.

Another object of the present disclosure is to provide an improved display device, which address the limitations and disadvantages associated with the related art.

The objects of the present disclosure are not limited to the above-described objects, and other objects that are not mentioned will be clearly understood by those skilled in the art from the following description.

A display device according to one or more aspects of the present disclosure includes a substrate; a plurality of pixels disposed on the substrate; an encapsulation portion disposed on the plurality of pixels; a plurality of touch electrodes disposed on the encapsulation portion; and a black matrix disposed on the plurality of touch electrodes, wherein the plurality of touch electrodes include a plurality of first opening holes that expose each of the plurality of pixels and a second opening hole larger than the plurality of first opening holes.

According to aspects of the present disclosure, the plurality of touch electrodes can be disposed to overlap the black matrix.

According to aspects of the present disclosure, each of the plurality of first opening holes can expose one pixel, and the plurality of first opening holes can have different sizes from each other.

According to aspects of the present disclosure, the second opening hole can expose more pixels than the first opening hole.

According to aspects of the present disclosure, the plurality of touch electrodes can include a plurality of first touch electrodes arranged in a first direction, and a plurality of second touch electrodes arranged in a second direction intersecting the first direction, and the second opening hole can be disposed in each of the plurality of first touch electrodes and second touch electrodes.

According to aspects of the present disclosure, a total area of the second opening hole in the touch electrodes can be smaller than a total area of the plurality of first opening holes.

According to aspects of the present disclosure, the display device can include a mesh pattern disposed in the second opening holes, and the mesh pattern can be electrically connected to the touch electrode.

According to aspects of the present disclosure, the display device can include an auxiliary electrode disposed to overlap the second opening hole.

According to aspects of the present disclosure, the display device can further include a bridge electrode connecting the plurality of second touch electrodes, and the auxiliary electrode can be disposed on the same layer as the bridge electrode.

According to aspects of the present disclosure, the display device can further include: a first touch insulating layer disposed on the encapsulation portion; and a second touch insulating layer disposed on the bridge electrode and the auxiliary electrode, wherein the bridge electrode can electrically connect the plurality of second touch electrodes, and the auxiliary electrode can be electrically connected to the touch electrode formed with the second opening hole by a through hole disposed in the second touch insulating layer.

According to aspects of the present disclosure, the auxiliary electrode can have a mesh shape.

According to aspects of the present disclosure, a total area of the second opening hole in one of the plurality of touch electrodes can be greater than or equal to a total area of the plurality of first opening holes in the one of the plurality of touch electrodes.

According to aspects of the present disclosure, a shape of the second opening hole in one of the plurality of touch electrodes can correspond to a shape of the one of the plurality of touch electrodes.

According to aspects of the present disclosure, the second opening hole in the one of the plurality of touch electrodes can have a quadrangular shape, while the one of the plurality of touch electrodes can have a quadrangular shape.

A display device according to another example of the present disclosure includes a substrate; a plurality of pixels disposed on the substrate; an encapsulation portion disposed on the plurality of pixels; an auxiliary electrode disposed on the encapsulation portion; a touch insulating layer disposed on the auxiliary electrode; a plurality of touch electrodes disposed on the touch insulating layer; and a black matrix disposed on the plurality of touch electrodes, wherein the plurality of touch electrodes include a second opening hole that exposes the auxiliary electrode.

According to aspects of the present disclosure, the plurality of touch electrodes can further include a plurality of first opening holes that expose each of the plurality of pixels, and the second opening hole can be larger than the plurality of first opening holes.

According to aspects of the present disclosure, the auxiliary electrode can further include a plurality of third opening holes that expose each of the plurality of pixels, and the third opening holes can be larger than the first opening holes.

According to aspects of the present disclosure, each of the plurality of first opening holes can expose one pixel, and the plurality of first opening holes can have different sizes from each other.

In the embodiments of the present disclosure, the exposing may refer to ensuring that the touch electrode does not cover the pixel or auxiliary electrode.

The black matrix covers an upper surface and side surface of the touch electrodes.

In another aspect, the present disclosure may provide a display device comprising: a substrate; a plurality of pixels disposed on the substrate; a plurality of touch electrodes disposed over the plurality of pixels; and a black matrix disposed on the plurality of touch electrodes, wherein the plurality of touch electrodes include: a first region having a first touch electrode and a second touch electrode; and a second region not having the first touch electrode and the second touch electrode; wherein the area of the second region is different from the area of the first region.

In some embodiments, the first touch electrode is disposed along a first direction and the second touch electrode is disposed along a second direction different from the first direction and the first touch electrode is disposed on a same layer of or a different layer from the second touch electrode.

The first region includes a plurality of first opening holes, and the plurality of first opening holes overlap with a plurality of pixels, respectively; the second region includes a second opening hole, and the second opening hole overlaps with a greater number of pixels than the first opening; and the area of the second region is smaller than the area of the first region.

An auxiliary electrode may be also disposed in the second region, the auxiliary electrode being disposed on a different layer from the touch electrode.

In another embodiment, the plurality of pixels includes a red pixel, green pixel, and blue pixel, and one of the plurality of first openings overlaps one of the red pixels, green pixels, and blue pixels, while the second opening overlaps a plurality of pixels among the re pixels, green pixels, and blue pixels.

The inventors of the present disclosure have recognized limitations of conventional display devices in which touch electrodes are visible and their areas are limited by manufacturing constraints, and have performed various experiments on touch electrodes disposed under a black matrix, which may allow an increased electrode area while maintaining low visibility and satisfying metal density requirements of vacuum equipment.

### BRIEF DESCRIPTION OF THE DRAWINGS

The above and other objects, features and advantages of the present invention will become more apparent to those of ordinary skill in the art by describing example disclosures thereof in detail with reference to the accompanying drawings, in which:

FIG. 1 is a conceptual diagram of a display device according to one or more embodiments of the present disclosure;

FIG. 2 is a conceptual diagram of a touch panel according to one or more embodiments of the present disclosure;

FIG. 3 is a conceptual diagram of a touch electrode according to one or more embodiments of the present disclosure;

FIG. 4 is an example of a partially enlarged view of FIG. 3;

FIG. 5 is an example of a view showing a mesh-type touch electrode;

FIG. 6 is an example of a cross-sectional view taken along line A-A′ in FIG. 4;

FIGS. 7 to 9 are views showing various modified examples of a second opening hole formed in a touch electrode according to one or more embodiments of the present disclosure;

FIG. 10 is a conceptual diagram of an example of a touch electrode according to one or more embodiments of the present disclosure;

FIG. 11 is an example of a partially enlarged view of FIG. 10;

FIG. 12 is an example of a cross-sectional view taken along line B-B′ in FIG. 11;

FIG. 13 is an example of a cross-sectional view taken along line C-C′ in FIG. 11;

FIG. 14 is a view showing a connection structure of the touch electrode and an auxiliary electrode according to an example of the present disclosure; and

FIGS. 15 and 16 are views showing various modified examples of an auxiliary electrode disposed in the touch electrode according to one or more embodiments of the present disclosure.

### DETAILED DESCRIPTION OF THE EMBODIMENTS

Advantages and features of the present disclosure and methods of achieving them will become apparent with reference to the following disclosures, which are described in detail, in conjunction with the accompanying drawings. However, the present disclosure is not limited to the disclosures to be described below and can be implemented in various different forms, the disclosures are only provided to completely disclose the present disclosure and completely convey the scope of the present disclosure to those skilled in the art.

Since the shapes, sizes, proportions, angles, numbers, and the like disclosed in the drawings for describing the disclosures of the present disclosure are only examples, the present disclosure is not limited to the items shown in the drawings. The same reference number indicates the same components throughout the specification. Further, in describing the present disclosure, when it is determined that a detailed description of related known technology can unnecessarily obscure the gist of the present disclosure, the detailed description thereof will be omitted.

When terms such as ‘providing,’ ‘including,’ ‘having,’ ‘consisting of,’ and the like mentioned in the present specification are used, other parts can be added unless ‘only’ is used. A case in which a component is expressed in a singular form can include a plural form unless explicitly stated otherwise.

In interpreting a component, the component is interpreted as including a margin of error even when there is no separate explicit description of the margin of error.

When a positional relationship and an interconnection relationship between two components are described using terms such as ‘on,’ ‘at an upper portion,’ ‘at a lower portion,’ ‘next to,’ ‘connect or couple,’ ‘crossing or intersecting,’ or the like are described, one or more other components can be interposed between the components unless there is a mention such as ‘immediately’ or ‘directly.’

When temporal relationships are described as using terms such as “after,” “following,” “and then,” “before,” and the like may not be continuous on a time axis unless “immediately” or “directly” is used.

The terms such as ‘first,’ ‘second,’ and the like can be used to distinguish components, but the functions or structures of these components are not limited by the ordinal numbers in front of the components or component names.

The following disclosures can be partially or entirely combined with each other, and technically, various interconnections and operations are possible. The disclosures can be implemented independently of each other or together in a related relationship. Further, the term “can” fully encompasses all the meanings and coverages of the term “may” and vice versa.

Hereinafter, various examples of the present disclosure will be described in detail with reference to the accompanying drawings. All the components of each display device/apparatus according to all embodiments of the present disclosure are operatively coupled and configured.

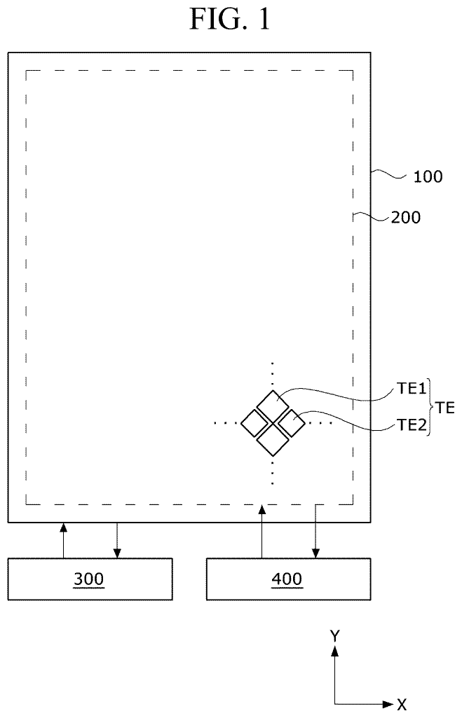

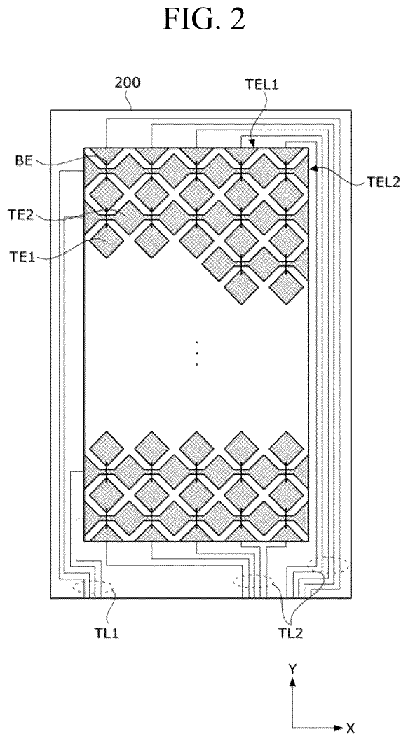

FIG. 1 is a conceptual diagram of a display device according to one or more embodiments of the present disclosure. FIG. 2 is a conceptual diagram of a touch panel according to one or more embodiments of the present disclosure;

Referring to FIGS. 1 and 2, the display device according to the present disclosure can provide an image display function for displaying an image and a touch sensing function for sensing a user's touch.

The display device according to the disclosures can include a display panel 100 on which data lines and gate lines are disposed, and a data driver 300 for driving the display panel 100.

The data driver 300 can include a data driving circuit for driving the data lines, a gate driving circuit for driving the gate lines, a controller for controlling the data driving circuit and the gate driving circuit, and the like. The data driver 300 can be implemented with one or more integrated circuits.

The display device according to the disclosure can include a touch panel 200 on which a plurality of touch electrodes TE are disposed and a plurality of touch lines TL1 and TL2 electrically connected to all or some of the plurality of touch electrodes TE are disposed, and a touch circuit portion 400 which drives the touch panel 200 to sense the presence or absence of a touch or a touch position.

The touch circuit portion 400 can supply a touch driving signal to a first touch electrode TE1 to drive the touch panel 200 and detect a touch sensing signal from a second touch electrode TE2 to sense the presence or absence of the touch and/or the touch position (touch coordinates).

The touch circuit portion 400 can include a touch driving circuit which supplies the touch driving signal and receives the touch sensing signal, a touch controller which calculates the touch coordinates, and the like. The touch driving signal can be a direct current signal having a constant voltage value, or can also be an alternating current signal which swings between a high level and a low level with a predetermined amplitude and is formed of a plurality of pulses.

The touch circuit portion 400 can be implemented with one or more components (for example, integrated circuits) and can be separately implemented from the data driver 300. However, the disclosures are not limited thereto. All or part of the touch circuit portion 400 can be implemented to be integrated with the data driver 300. For example, the touch driving circuit of the touch circuit portion 400 can be implemented as an integrated circuit along with the data driving circuit of the data driver 300.

The touch panel 200 can sense a touch using a mutual-capacitance-based touch sensing method which is a capacitance-based touch sensing method. In the case of the mutual-capacitance-based touch sensing method, the presence or absence of the touch and/or the touch coordinates can be detected based on a change in capacitance (mutual capacitance) between a driving electrode and a sensing electrode depending on the presence or absence of a pointer such as a finger, a pen, or the like. However, the disclosures are not limited thereto, and the touch can also be sensed using a self-capacitance-based touch sensing method.

In the case of the self-capacitance-based touch sensing method, each touch electrode TE can serve as both the driving electrode and the sensing electrode.

For example, the touch driving signal can be applied to each touch electrode TE, and the touch sensing signal can be received through the touch electrode TE to which the touch driving signal is applied. Accordingly, in the self-capacitance-based touch sensing method, there is no distinction between the driving electrode and the sensing electrode.

In the self-capacitance-based touch sensing method, the presence or absence of the touch and/or the touch coordinates can be detected based on a change in capacitance between a pointer such as a finger, a pen, or the like and the touch electrode TE.

Hereinafter, the mutual-capacitance-based touch sensing method will be described.

The plurality of touch electrodes TE can include the first touch electrode TE1 to which a touch driving signal is applied, and the second touch electrode TE2 which senses a touch sensing signal. The first touch electrode TE1 can be defined as a driving electrode, a touch driving electrode, a driving touch electrode, or the like, and the second touch electrode TE2 can be defined as a sensing electrode, a touch sensing electrode, a sensing touch electrode, or the like.

A plurality of first touch electrodes TE1 can be connected to each other in a second direction (a Y-axis direction) to form a driving electrode line TEL1, and a plurality of second touch electrodes TE2 can be connected to each other in a first direction (an X-axis direction) to form a sensing electrode line TEL2. The plurality of second touch electrodes TE2 can be connected to each other by a bridge electrode BE. However, the present disclosure is not limited thereto, and the first touch electrodes TE1 can be connected to each other by the bridge electrode BE.

In the disclosure, the plurality of first touch electrodes TE1 are described as being connected in the second direction, but the disclosures are not limited thereto. For example, the plurality of first touch electrodes TE1 can be connected to each other in the first direction to form the driving electrode line, and the plurality of second touch electrodes TE2 can be connected to each other in the second direction to form the sensing electrode line.

The touch panel 200 can include the touch lines TL1 and TL2 connected to the touch circuit portion 400 to electrically connect the touch electrodes TE and the touch circuit portion 400. The touch electrodes TE and the touch lines TL1 and TL2 can be disposed on the same layer or on different layers.

The touch panel 200 according to the disclosures can be disposed in the display panel 100, but is not limited thereto. For example, the touch panel 200 can be disposed on the outside of the display panel 100. When the touch panel 200 is an external type, the touch panel 200 and the display panel 100 can be separately manufactured through different panel manufacturing processes and then bonded. When the touch panel 200 is a built-in type, the touch panel 200 and the display panel 100 can be manufactured together through a single panel manufacturing process.

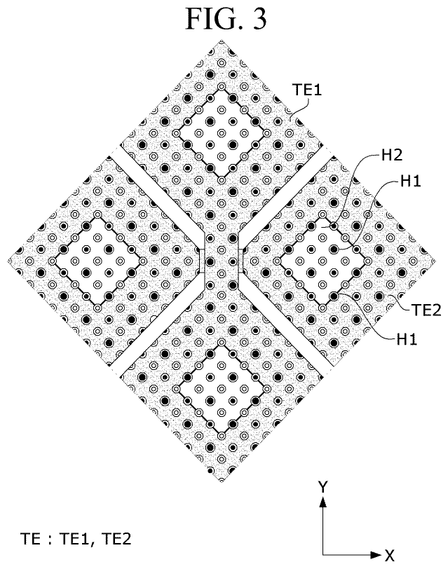

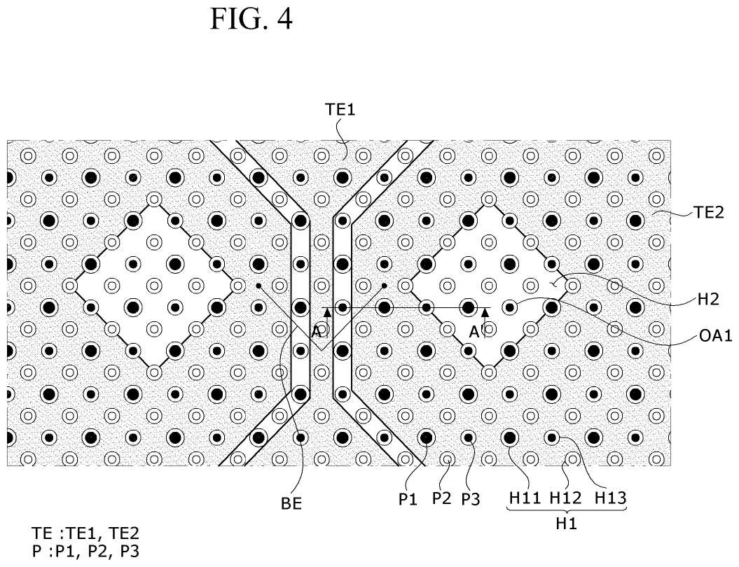

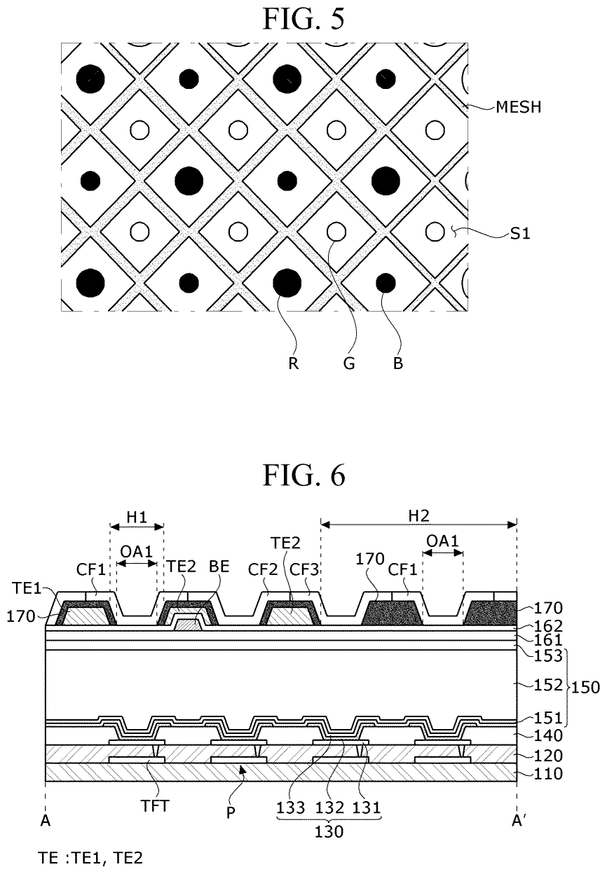

FIG. 3 is a conceptual diagram of the touch electrode according to one or more embodiments of the present disclosure. FIG. 4 is an enlarged view of an example of a partially enlarged view in FIG. 3. FIG. 5 is a view showing a mesh-type touch electrode according to an example of the present disclosure.

Referring to FIGS. 3 and 4, the touch electrodes TE may include the first touch electrode TE1 disposed in the second direction (e.g. Y direction) and the second touch electrode TE2 disposed in the first direction (e.g. X direction). The disclosures are not limited thereto and the first touch electrode TE1 may be disposed in the first direction, while the second touch electrode TE2 may be disposed in the second direction. The first touch electrode TE1 may be a driving electrode and the second touch electrode TE2 may be a sensing electrode, but the disclosures are not limited thereto. For example, the first touch electrode TE1 may be a sensing electrode and the second touch electrode TE2 may be a driving electrode.

A shape of the touch electrode TE can be a quadrangular shape, but is not limited thereto. For example, the touch electrode TE can have a polygonal shape such as an octagonal shape.

The touch electrode TE can include a first opening hole H1 and a second opening hole H2 which expose a plurality of pixels. The first opening hole H1 can have a size sufficient to expose each pixel P. The first opening hole H1 can have a different diameter depending on the size of the pixel P. The first opening hole H1 can include a 1-1 opening hole H11 which exposes a first pixel P1, a 1-2 opening hole H12 which exposes a second pixel P2, and a 1-3 opening hole H13 which exposes a third pixel P3. For example, when the sizes of the pixels increase in the order of the second pixel P2, the third pixel P3, and the first pixel P1 (P2<P3<P1), the size of the first opening hole H1 can also increase in the order of the 1-2 opening hole H12, the 1-3 opening hole H13, and the 1-1 opening hole H11. For example, the diameter of the first opening hole H1 can vary depending on the size of the pixel. The first pixel P1 may be a red subpixel R, the second pixel P2 may be a blue subpixel B, and the third pixel P3 may be a green subpixel G, but the size of each pixel may vary. When the pixel further includes a white subpixel, the first opening hole H1 may further include a 1-4 opening hole which exposes the white subpixel. In embodiments of the present disclosure, the term “expose” may refer to ensure that the touch electrode does not cover the pixel or auxiliary electrode such that light from the pixel can emit to the outside. The plurality of first opening holes H1 may expose red subpixel R, blue subpixel B, and green subpixel G, respectively, and the second opening holes H2 may expose more pixels among the red subpixel R, blue subpixel B, and green subpixel G.

According to some aspects of the present disclosure, since the touch electrodes TE are disposed under a black matrix 170, the touch electrodes TE may not be visible from the outside. Accordingly, the touch electrodes TE can be disposed as widely as possible in a region where the black matrix 170 is disposed to improve sensing sensitivity. The black matrix 170 may overlap the top of the touch electrodes. In some embodiments, the black matrix 170 may overlap the top and side surfaces of the touch electrodes.

The touch electrode TE may be formed on the touch panel using vacuum equipment having a set allowable limit of a metal density at which the process may proceed. Due to process window control requirements, it is necessary to set ranges for local metal pattern density, wherein it is typically unallowable to make a complete coverage of metal patterns, which may violate process design rules. In the present disclosure, the allowable limit of the metal density set in the vacuum equipment may mean a density occupied by metal in the vacuum equipment. However, it is not necessarily limited to this and may also refer to the allowable metal density of vacuum equipment. Each vacuum equipment may have a set allowable metal density depending on the vacuum level.

Accordingly, when the allowable limit of the metal density is high, a large amount of metal can be injected into the vacuum equipment and thus the touch electrode TE can be widely formed, but when the allowable limit of the metal density is low, the metal density in the vacuum equipment is low and thus it is difficult to form a large area for the touch electrode TE.

The allowable metal density can vary depending on the vacuum equipment. Accordingly, in order to meet the allowable limit of the metal density of the vacuum equipment to be used, it is necessary to adjust the area of the touch electrode TE.

According to some aspects of the present disclosure, the second opening hole H2 can be formed in the touch electrode TE. The second opening hole H2 can be disposed at a center of the touch electrode TE, but is not limited thereto. For example, the second opening hole H2 can be disposed at an edge of the touch electrode TE. The second opening hole H2 can be divided into a plurality of second opening holes H2. A total area of the second opening hole H2 in the touch electrode TE can be smaller than a total area of a plurality of first opening holes H1. However, the present disclosure is not limited thereto, and the total area of the second opening hole H2 in the touch electrode TE can be greater than or equal to the total area of the plurality of first opening holes H1.

The second opening hole H2 can be formed to adjust the area of the touch electrode TE according to the allowable limit of the metal density of the vacuum equipment. In a conventional touch structure, dummy metal is left in a floating state to maintain constant reflectivity, but according to the disclosure, there is a difference in that a dummy electrode is removed and the second opening hole H2 is formed to allow the vacuum process. Further, in the disclosure, since the touch electrode TE is disposed under the black matrix, a visibility issue does not occur even when the dummy electrode is removed.

The second opening hole H2 can be formed to correspond to the shape of the touch electrode TE. For example, when the touch electrode TE has a quadrangular shape, the second opening hole H2 can also have a quadrangular shape. However, the disclosures are not limited thereto. For example, the touch electrode TE can have an octagonal shape and the second opening hole H2 can have a quadrangular shape.

Referring to FIG. 5, a touch electrode TE having a mesh structure has been conventionally used for visibility, but there is an issue that resistance relatively increases due to the increased area S1 of the thin mesh lines, and thus sensing sensitivity is low. However, according to the disclosure, since the touch electrode TE is entirely disposed under the black matrix 170, there is an advantage of disposing the touch electrode TE as widely as possible to lower the resistance.

FIG. 6 is a cross-sectional view taken along line A-A′ in FIG. 4.

Referring to FIG. 6, the display device according to the disclosure can include a substrate 110, a plurality of pixels P disposed on the substrate 110, an encapsulation portion 150 disposed on the plurality of pixels, a plurality of touch electrodes TE disposed on the encapsulation portion 150, and the black matrix 170 disposed on the plurality of touch electrodes TE. Each of the plurality of pixels P can include a light-emitting element 130 and a driving circuit including a thin film transistor TFT.

The substrate 110 can include an insulating material. For example, the substrate 110 can include glass or plastic. A buffer layer can be disposed on the substrate 110. The buffer layer can prevent contamination by the substrate during the formation process of the driving circuit.

A driving circuit including a plurality of thin film transistors TFT can be disposed on the substrate 110. The thin film transistor TFT can generate a driving current corresponding to a data signal. The thin film transistor can be an oxide thin film transistor or a low temperature polycrystalline silicon (LTPS) thin film transistor.

A planarization layer 120 can remove a step caused by the driving circuit of each pixel. For example, an upper surface of the planarization layer 120 facing the substrate 110 can be a flat plane. The planarization layer 120 can include an organic insulating material. A plurality of insulating layers can be further disposed between the planarization layer 120 and the substrate 110.

The light-emitting element 130 can emit light of a specific color. For example, the light-emitting element 130 of each pixel can include a first electrode 131, a light-emitting layer 132, and a second electrode 133 sequentially stacked on the substrate 110.

The first electrode 131 may include a conductive material. The first electrode 131 may include a material having high reflectivity. For example, the first electrode 131 may include a metal such as aluminum (Al) or silver (Ag). In an alternative embodiment, the first electrode 131 may also be formed of aluminum (Al), copper (Cu), silver (Ag), nickel (Ni), palladium (Pd), or a combination thereof. The first electrode 131 may have a multilayer structure. For example, the first electrode 131 may have a structure in which a reflective electrode made of metal is positioned between transparent electrodes made of a transparent conductive material such as ITO or IZO. In another embodiment, the first electrode 131 may also be formed of an Ag/Pd/Cu (APC) alloy.

The light-emitting layer 132 can generate light having a brightness corresponding to a voltage difference between the first electrode 131 and the second electrode 133. For example, the light-emitting layer 132 can include an emission material layer EML including a light-emitting material. The light-emitting material can include an organic material, an inorganic material, or a hybrid material. For example, the display device according to the disclosure of the present disclosure can be an organic light-emitting display device including an organic light-emitting material.

The light-emitting layer 132 can have a multilayer structure. For example, the light-emitting layer 132 can include a hole injection layer HIL, a hole transport layer HTL, an electron transport layer ETL, and an electron injection layer EIL.

However, the disclosures of the present disclosure are not limited thereto. The light-emitting element 130 can include an inorganic material light-emitting layer 132. In this case, the light-emitting layer 132 can include a micro-sized inorganic light-emitting layer.

The second electrode 133 can include a conductive material. The second electrode 133 can include a different material from the first electrode 131. The transmittance of the second electrode 133 can be greater than the transmittance of the first electrode 131. For example, the second electrode 133 can be a transparent electrode made of a transparent conductive material such as ITO or IZO. Accordingly, in the display device according to the disclosure of the present disclosure, light generated by the light-emitting layer 132 can be emitted to the outside through the second electrode 133.

A bank layer 140 can be located on the planarization layer 120. The bank layer 140 can define a light-emitting region in each pixel. For example, the bank layer 140 can cover an edge of the first electrode 131. The light-emitting layer 132 and the second electrode 133 can be sequentially stacked on a portion of the first electrode 131 exposed by the bank layer 140. The bank layer 140 can include an insulating material. For example, the bank layer 140 can include an organic insulating material.

At least a portion of the light-emitting layer 132 of each pixel can extend outside the pixel. For example, at least one of the hole injection layer HIL, the hole transport layer HTL, the electron transport layer ETL, and the electron injection layer EIL located in each pixel can extend onto the bank layer 140. At least one of the hole injection layer HIL, the hole transport layer HTL, the electron transport layer ETL, and the electron injection layer EIL located in each pixel can be simultaneously formed with a corresponding layer located in an adjacent pixel. For example, at least one of the hole injection layer HIL, the hole transport layer HTL, the electron transport layer ETL, and the electron injection layer EIL can be formed on the entire surface of the substrate 110.

The encapsulation portion 150 can be located on the light-emitting element of each pixel. The encapsulation portion 150 can prevent damage to the light-emitting element due to external moisture and impacts. For example, the light-emitting element 130 of each pixel can be completely covered by the encapsulation portion 150.

The encapsulation portion 150 can have a multilayer structure. For example, the encapsulation portion 150 can include a first encapsulation layer 151, a second encapsulation layer 152, and a third encapsulation layer 153. The first encapsulation layer 151, the second encapsulation layer 152, and the third encapsulation layer 153 can include insulating materials.

The second encapsulation layer 152 can include a different material from the first encapsulation layer 151 and the third encapsulation layer 153. For example, the first encapsulation layer 151 and the third encapsulation layer 153 can include an inorganic insulating material, and the second encapsulation layer 152 can include an organic insulating material. Accordingly, the damage to the light-emitting element due to external moisture and impacts can be effectively prevented.

Since the second encapsulation layer 152 is formed relatively thick, a step due to the light-emitting element can be removed by the second encapsulation layer 152. For example, an upper surface of the encapsulation portion 150 facing the substrate 110 can be a flat plane. Further, a parasitic capacitance between the second electrode 133 of the light-emitting element and the touch electrode TE can be reduced by the second encapsulation layer 152. A thickness of the second encapsulation layer 152 can be 5 μm or more, but is not limited thereto.

A first touch insulating layer 161 can be disposed on the encapsulation portion 150. The first touch insulating layer 161 can block a chemical solution such as a developer or an etchant used in a manufacturing process of the touch electrodes TE, or external moisture or foreign substances from penetrating into the light-emitting element.

The bridge electrode BE can be disposed on the first touch insulating layer 161. The bridge electrode BE can be disposed at a position which connects the plurality of second touch electrodes TE2 among the touch electrodes TE. The bridge electrode BE can include the same material as the touch electrode TE, but can also include different materials.

A second touch insulating layer 162 can be disposed on the first touch insulating layer 161 to cover the bridge electrode BE and insulate the bridge electrode BE and the touch electrode TE. The second touch insulating layer 162 can be disposed between the bridge electrodes BE and can insulate the bridge electrodes BE from each other. Some of the second touch electrodes TE2 can be connected to the bridge electrodes BE by through holes.

The first touch insulating layer 161 and/or the second touch insulating layer 162 can be made of an inorganic insulating material such as silicon nitride (SiNₓ) or silicon oxide (SiOₓ).

The black matrix 170 can be located on the touch electrode TE. According to some aspects of the present disclosure, since the black matrix 170 is disposed on the touch electrode TE, external light can be prevented from being reflected by the touch electrode TE. Accordingly, the touch electrodes TE can be disposed as widely as possible.

The black matrix 170 may include a plurality of opening regions OA1, and the plurality of opening regions OA1 may be disposed at positions overlapping the first opening holes H1 of the touch electrode TE. Accordingly, light emitted from the light-emitting element 130 may be emitted to the outside through the first opening hole H1 and the opening region OA1. As can be seen from FIG. 6, the area of the first opening H1 can correspond to the gap between the two adjacent first touch electrodes TE1 and second touch electrodes TE2. The opening region OA1 may correspond to the distance between two adjacent black matrix 170. The first opening hole H1 of the touch electrode TE may have a wider diameter than the opening region OA1 of the black matrix 170. In this embodiment, the black matrix 170 may cover the upper and side surfaces of the touch electrode, which facilitates the invisibility of the touch electrode TE. However, the embodiments of the invention are not limited thereto. The black matrix 170 can overlap with the touch electrode in other ways.

In the second opening hole H2 of the touch electrode TE, the black matrix 170 may be disposed on the second touch insulating layer 162. The second opening hole H2 may overlap a plurality of opening regions OA1 of the black matrix 170. That is, one first opening hole H1 overlaps one opening region OA1, but one second opening hole H2 may overlap a plurality of opening regions OA1. Referring to FIG. 6, it can also be seen that the second opening hole H2 may be a partial area where no touch electrode exists. In this case, the first touch electrode TE1 and the second touch electrode TE2 are not arranged in the area of the second opening hole H2. The black matrix 170 is disposed on the touch insulating layer without covering the touch electrode. In some embodiments, a region where touch electrodes are provided may be referred to as the first region, while the region where no touch electrodes are provided may be referred to as the second region.

According to some aspects of the present disclosure, the black matrix 170 can be directly disposed on the touch electrode TE, but is not limited thereto. For example, a separate touch protection layer can be disposed between the touch electrode TE and the black matrix 170.

The touch protection layer can be disposed on the touch electrode TE. The touch protection layer can serve to prevent oxidation, corrosion, or damage to the touch electrode TE and the touch line. The touch protection layer can be made of at least one or more materials among inorganic insulating materials such as silicon nitride (SiNₓ) and silicon oxide (SiOₓ), or organic insulating materials such as an acrylic resin, an epoxy resin, a phenolic resin, a polyamide resin, and a polyimide resin, but is not limited thereto.

Color filters CF1, CF2, and CF3 can be disposed in the opening regions OA1 of the black matrix 170. Color filters having the same color as the light emitted from each light-emitting element 130 can be disposed as the color filters CF1, CF2, and CF3, respectively. According to some aspects of the present disclosure, as a plurality of color filters CF1, CF2, and CF3 can be located at positions corresponding to the plurality of opening regions, excellent light-emitting performance can be achieved.

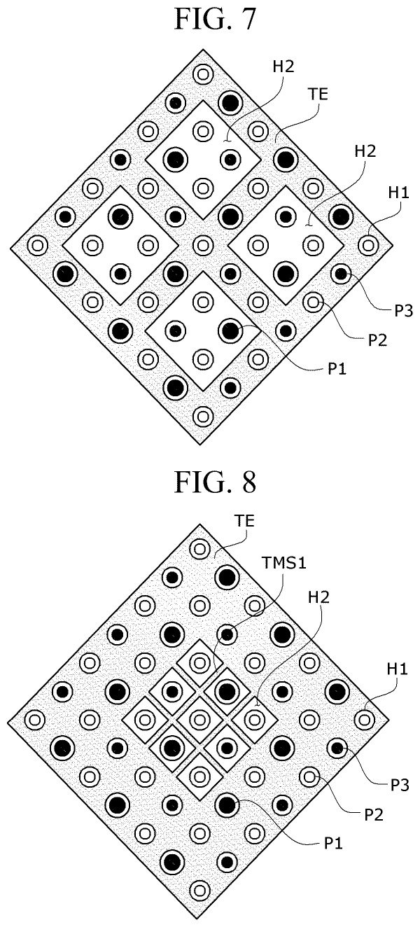

FIGS. 7 to 9 are views showing various modified examples of the touch electrodes according to aspects of the present disclosure.

Referring to FIG. 7, the touch electrode TE may include a plurality of first opening holes H1 and a plurality of second opening holes H2. According to the disclosure, the second opening hole H2 may be divided into a plurality of second opening holes H2 and disposed spaced apart from each other. When the second opening holes H2 are disposed at a predetermined interval, since the resistance distribution in the touch electrodes TE becomes more uniform, sensing sensitivity may be improved. In the embodiment shown in FIG. 7, the second opening holes H2 is arranged symmetrically around the central region of the touch electrode. The symmetrical arrangement may be advantageous in some embodiments for improving sensing sensitivity. However, in some other embodiments, the arrangement of the second opening hole H2 may not be exactly symmetrical (as shown in FIG. 3).

Referring to FIG. 8, a plurality of conductive lines TMS1 may be formed in the second opening holes H2 of the touch electrode TE. According to this configuration, sensing sensitivity may be improved by forming the plurality of conductive lines TMS1 in the second opening holes H2 while maintaining the metal density. In other words, one or more conductive lines TMS1 are inserted in areas where no touch electrode TE exists to improve sensing sensitivity. The density of one or more conductive lines TMS1 may be lower than the arrangement density of touch electrodes TE.

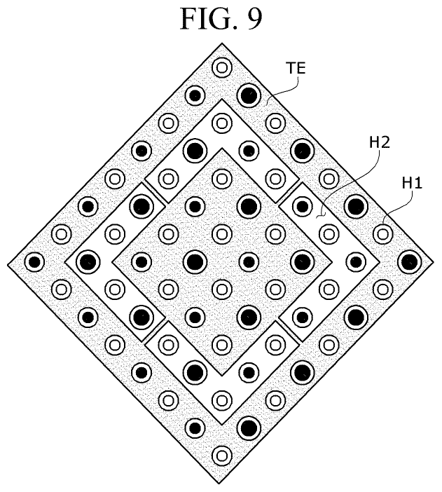

Referring to FIG. 9, the second opening hole H2 may be disposed at an edge of the touch electrode TE. In this case, the second opening hole H2 may be formed by connecting the plurality of first opening holes H1. The second opening hole H2 extends along the edge of the touch electrode TE and covers multiple first openings holes H1. The shape of one or more second opening holes H2 can be substantially the same as the shape of the touch electrode TE. For instance, if the touch electrode TE is quadrilateral, the one or more second opening hole H2 may also be quadrilateral and surround the central portion of the touch electrode TE. A width of the second opening hole H2 may be greater than or equal to a diameter of the first opening hole H1. In this way, the position and shape of the second opening hole H2 may be variously modified within a range which satisfies the metal density.

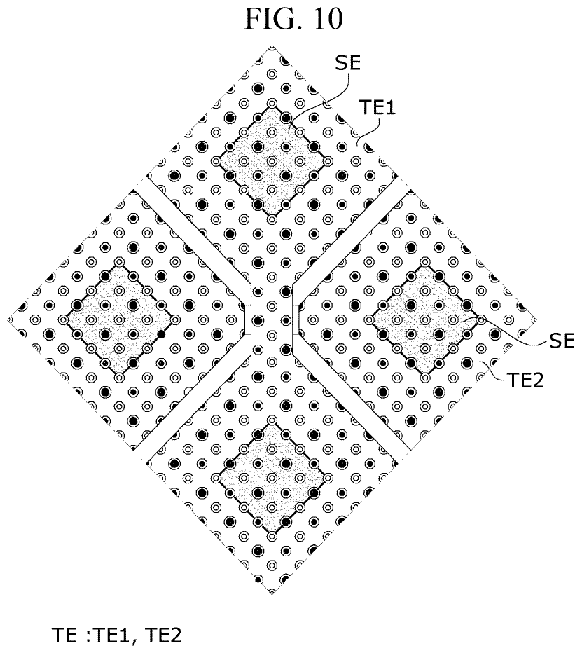

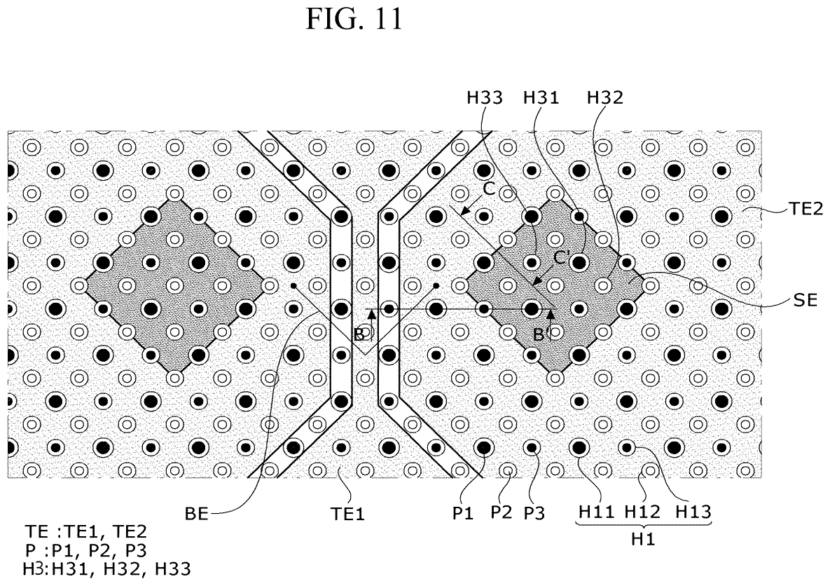

FIG. 10 is a conceptual diagram of a touch electrode according to another example of the present disclosure. FIG. 11 is a partially view of in FIG. 10.

Referring to FIGS. 10 and 11, a touch electrode TE can include a first opening hole H1 and a second opening hole H2 which expose a plurality of pixels. The first opening hole H1 can have a size sufficient to expose one pixel P. The first opening hole H1 can have a different diameter depending on a size of the pixel P.

The first opening hole H1 can include a 1-1 opening hole H11 which exposes a first pixel P1, a 1-2 opening hole H12 which exposes a second pixel P2, and a 1-3 opening hole H13 which exposes a third pixel P3.

For example, when the sizes of the pixels increase in the order of the second pixel P2, the third pixel P3, and the first pixel P1 (P2<P3<P1), the size of the first opening hole H1 can also increase in the order of the 1-2 opening hole H12, the 1-3 opening hole H13, and the 1-1 opening hole H11. For example, the diameter of the first opening hole H1 can vary depending on the size of the pixel P.

According to some aspects of the present disclosure, the second opening hole H2 can be formed in the touch electrode TE. The second opening hole H2 can be disposed at a center of the touch electrode TE, but is not limited thereto. For example, the second opening hole H2 can be disposed at an edge of the touch electrode TE. The second opening hole H2 can be formed to adjust a metal density of the touch electrode TE.

The touch electrode TE may include an auxiliary electrode SE exposed through the second opening hole H2. The auxiliary electrode SE may be disposed on the same layer as the bridge electrode BE. The auxiliary electrode SE may be manufactured simultaneously with the bridge electrode BE. A touch sensing region may have substantially the same area as the black matrix 170 due to the auxiliary electrode SE. In this embodiment, the auxiliary electrode SE fills the region corresponding to the second opening holes H2 on a different layer from the touch electrode TE. The auxiliary electrode SE and the touch electrode TE may be spaced apart from each other by the second touch insulating layer 162. In this structure, the touch electrode TE, the bridging electrode BE, and the auxiliary electrode SE meet the limitations on the metal occupancy of each layer in semiconductor design. Moreover, sensing sensitivity may be further improved.

The auxiliary electrode SE can be formed to correspond to a shape of the touch electrode TE. For example, when the touch electrode TE has a quadrangular shape, the auxiliary electrode SE can also have a quadrangular shape. However, the disclosures are not limited thereto. For example, the touch electrode TE can have an octagonal shape and the auxiliary electrode SE can have a quadrangular shape.

An area of the auxiliary electrode SE can be smaller than an area of the touch electrode TE. Since the auxiliary electrode SE can be formed to correspond to an area where the second opening hole H2 is formed to adjust an electrode density, the auxiliary electrode SE can have a smaller area than the touch electrode TE. However, the disclosures are not limited thereto. For example, when the size of the touch electrode TE is reduced, the area of the auxiliary electrode SE can be greater than or equal to the area of the touch electrode TE.

The auxiliary electrode SE can have a shape corresponding to the second opening hole H2. For example, when the second opening hole H2 has a quadrangular shape, the auxiliary electrode SE can also have a quadrangular shape. However, the present disclosure is not limited thereto, and the auxiliary electrode SE can have a different shape from the second opening hole H2. For example, the second opening hole H2 can have a quadrangular shape while the auxiliary electrode SE can have an octagonal shape.

The auxiliary electrode SE can have a smaller area than the second opening hole H2. When the auxiliary electrode SE has an area greater than the area of the second opening hole H2, it overlaps the touch electrode TE, resulting in parasitic capacitance. However, the present disclosure is not limited thereto, and the auxiliary electrode SE can have an area greater than or equal to the area of the second opening hole H2.

The auxiliary electrode SE can include a third opening hole H3 which exposes a plurality of pixels P. The third opening hole H3 can have the same diameter as the first opening hole H1. Accordingly, the third opening hole H3 can include a 3-1 opening hole H31 which exposes a first pixel P1, a 3-2 opening hole H32 which exposes a second pixel P2, and a 3-3 opening hole H33 which exposes a third pixel P3. A diameter of the 3-1 opening hole H31 can be the same as a diameter of the 1-1 opening hole H11. A diameter of the 3-2 opening hole H32 can be the same as a diameter of the 1-2 opening hole H12. A diameter of the 3 -3 opening hole H33 can be the same as a diameter of the 1-3 opening hole H13.

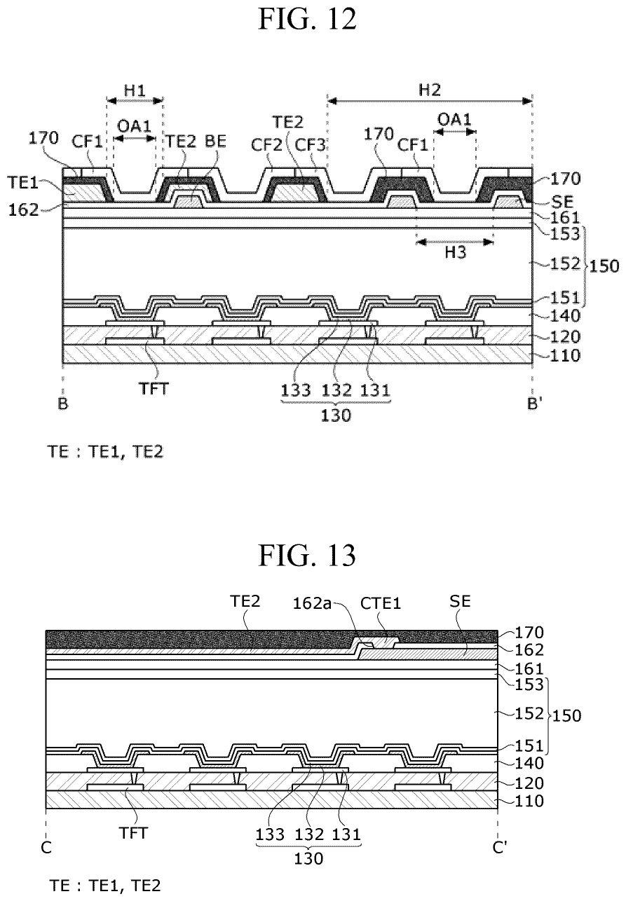

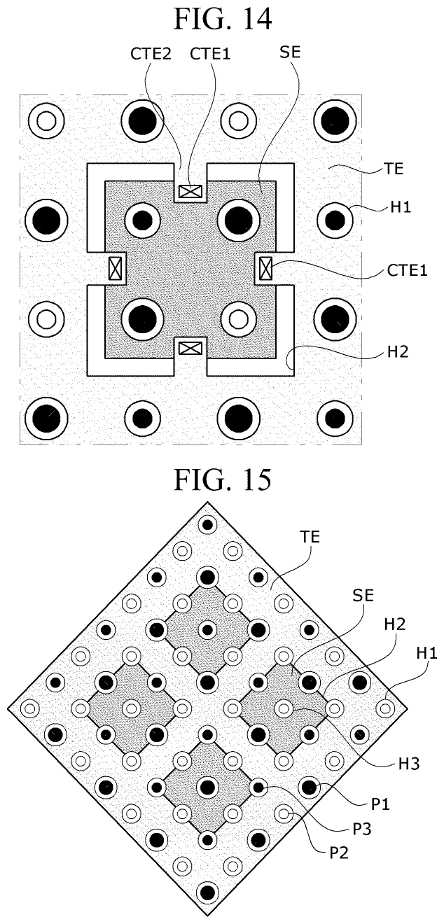

FIG. 12 is a cross-sectional view taken along line B-B′ in FIG. 11. FIG. 13 is a cross-sectional view taken along line C-C′ in FIG. 11. FIG. 14 is a view showing a connection structure of the touch electrode and the auxiliary electrode according to an example of the present disclosure.

Referring to FIG. 12, a bridge electrode BE and an auxiliary electrode SE can be disposed on a first touch insulating layer 161. A second touch insulating layer 162 can be disposed on the bridge electrode BE and the auxiliary electrode SE. The first touch insulating layer 161 and/or the second touch insulating layer 162 can be made of an inorganic insulating material such as silicon nitride (SiNₓ) or silicon oxide (SiOₓ).

The bridge electrode BE and the auxiliary electrode SE are manufactured in the same process, and thus can be made of the same material and can have the same thickness. However, the disclosure is not limited thereto. For example, the bridge electrode and the auxiliary electrode SE can have different thicknesses. The thickness of the auxiliary electrode SE can be manufactured the same as that of the touch electrode TE to uniformize sensing sensitivity.

According to some aspects of the present disclosure, since the touch electrode TE is formed after forming the second touch insulating layer 162 on the auxiliary electrode SE, the auxiliary electrode SE may not affect an electrode density required by vacuum equipment. Accordingly, according to the disclosure, since the auxiliary electrode SE is formed first and then the touch electrode TE is formed, a sensing region can be maximized while satisfying the metal density of the vacuum equipment.

In a region where the second opening hole H2 is formed, only the auxiliary electrode SE can be disposed without the touch electrode TE. Accordingly, in the region where the second opening hole H2 is formed, the auxiliary electrode SE can serve as the touch electrode TE.

The black matrix 170 can be located on the touch electrode TE. According to some aspects of the present disclosure, since the black matrix 170 is disposed on the touch electrode TE and the auxiliary electrode SE, external light can be prevented from being reflected by the touch electrode TE and the auxiliary electrode SE. Accordingly, the touch electrode TE and the auxiliary electrode SE can be disposed as widely as possible.

In the second opening hole H2, the black matrix 170 may be disposed on the auxiliary electrode SE. In this case, the second touch insulating layer 162 may be disposed between the black matrix 170 and the auxiliary electrode SE. The black matrix 170 may overlap the top of the auxiliary electrode SE, and the side of the black matrix 170 may laterally overlap the side surface of the auxiliary electrode SE.

According to some aspects of the present disclosure, an opening region OA1 of the black matrix 170 can be disposed at a position overlapping the first opening hole H1 of the touch electrode TE. Accordingly, light emitted from the light-emitting element can be emitted to the outside through the first opening hole H1 and the opening region OA1.

The black matrix 170 can be disposed on the second touch insulating layer 162 in a portion corresponding to the second opening hole H2 of the touch electrode TE. Accordingly, one second opening hole H2 can overlap a plurality of opening regions OA1 of the black matrix 170.

The first opening hole H1 of the touch electrode TE may have a wider diameter than the opening region OA1 of the black matrix 170. Further, the third opening hole H3 of the auxiliary electrode SE may have a wider diameter than the first opening hole H1 of the touch electrode TE and the opening region OA1 of the black matrix 170. In this embodiment, the width of the opening region OA1 may correspond to the distance between the opposite side edges of two adjacent black matrices covering the auxiliary electrode SE, and the width of the third opening hole H3 may correspond to the distance between the opposite side edges of two adjacent auxiliary electrodes SE.

According to some aspects of the present disclosure, the black matrix 170 can be directly disposed on the touch electrode TE, but is not limited thereto. For example, a separate touch protection layer can be disposed between the touch electrode TE and the black matrix 170.

Referring to FIGS. 13 and 14, since a through hole 162a is formed in the second touch insulating layer 162, a contact electrode CTE1 of the touch electrode TE can be electrically connected to the auxiliary electrode SE through the through hole 162a.

There can be a plurality of contact electrodes CTE1 of the touch electrode TE. The touch electrode TE can include a plurality of extending portions CTE2 extending into the second opening hole H2, and the contact electrodes CTE1 can be disposed at ends of the extending portions CTE2. Although the drawing shows that the touch electrode TE and the auxiliary electrode SE are spaced apart in a plan view, the auxiliary electrode SE can be formed with the same area as the second opening hole H2 of the touch electrode TE. Accordingly, the touch electrode TE and the auxiliary electrode SE can be disposed so that boundaries thereof overlap.

Although the examples of disclosure show that the extending portions of the touch electrode TE extend to an upper portion of the auxiliary electrode SE, the disclosures are not limited thereto. For example, extending portions of the auxiliary electrode SE can extend and can be electrically connected to a lower portion of the touch electrode TE.

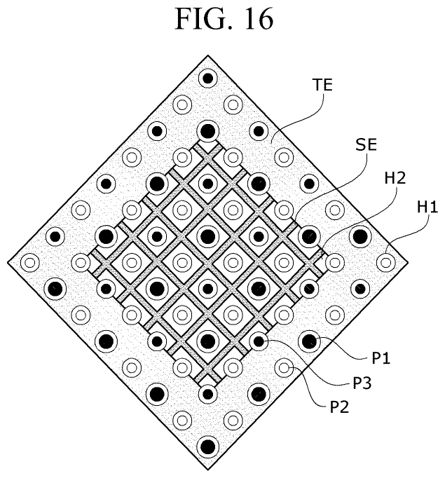

FIGS. 15 and 16 are views showing various modified examples of the touch electrode according to one or more embodiments of the present disclosure.

Referring to FIG. 15, the second opening hole H2 and the auxiliary electrode SE may be divided into a plurality of second opening holes H2 and auxiliary electrodes SE, and disposed spaced apart from each other. When the second opening holes H2 are disposed at a predetermined interval, since the resistance distribution in the touch electrodes TE becomes more uniform, sensing sensitivity may be improved. In this plan view of FIG. 15, the auxiliary electrode SE may cover the entire area of the second opening holes H2. However, the embodiment is not limited thereto. The auxiliary electrode SE may cover a portion of the area of the second opening holes H2.

Referring to another example in FIG. 16, the auxiliary electrode SE can have a mesh shape. According to this configuration, sensing sensitivity can be improved by forming a plurality of conductive lines in the second opening holes H2 while maintaining the metal density.

According to an example of the present disclosure, low reflectivity is possible and a visibility problem can be improved by disposing a touch electrode under a black matrix. Further, sensing sensitivity can be increased by increasing an area of the touch electrode. In addition, there is an advantage in securing touch performance as sensor design freedom increases.

In addition, according to some aspects of the present disclosure, the area of the touch electrode can be increased while adjusting the area of the touch electrode according to a metal density of vacuum equipment which manufactures a touch panel.

The effects of the present disclosure are not limited to the above-mentioned effects, and other effects which are not mentioned can be clearly understood by those skilled in the art from the following description.

Since the contents of the specification described the problems to be solved, the means to solve the problems, and the effects described above do not specify the essential features of the claims, the scope of the claims is not limited by the items described in the contents of the specification.

Although the disclosures have been described in more detail with reference to the accompanying drawings, the present disclosure is not necessarily limited to these disclosures, and can be variously modified without departing from the technical spirit of the present disclosure. Accordingly, the disclosures disclosed in the present disclosure are not intended to limit the technical spirit of the present disclosure, but intended to describe the same, and the scope of the technical spirit of the present disclosure is not limited by these disclosures. The scope of the present disclosure should be construed according to the appended claims, and all technical ideas within the equivalent range should be construed as being included in the scope of the present disclosure.

What is claimed is:

1. A display device comprising:
a substrate;
a plurality of pixels disposed on the substrate;
an encapsulation portion disposed on the plurality of pixels;
a plurality of touch electrodes disposed on the encapsulation portion; and
a black matrix disposed on the plurality of touch electrodes,
wherein the plurality of touch electrodes include:
a plurality of first opening holes configured to expose the plurality of pixels, and
a second opening hole larger than each of the plurality of first opening holes.

2. The display device of claim 1, wherein the plurality of touch electrodes are disposed to overlap the black matrix.

3. The display device of claim 1, wherein each of the plurality of first opening holes exposes one pixel among the plurality of pixels, and
some of the plurality of first opening holes have different sizes from each other.

4. The display device of claim 3, wherein the second opening hole exposes more pixels than each of the plurality of first opening holes.

5. The display device of claim 1, wherein the plurality of touch electrodes include:
a plurality of first touch electrodes arranged in a first direction; and
a plurality of second touch electrodes arranged in a second direction intersecting the first direction.

6. The display device of claim 5, wherein the second opening hole is disposed in each of the plurality of first touch electrodes and the plurality of second touch electrodes.

7. The display device of claim 2, wherein a total area of the second opening hole in the one of the plurality of touch electrodes is smaller than a total area of the plurality of first opening holes in the one of the plurality of touch electrodes.

8. The display device of claim 1, further comprising a mesh pattern disposed in the second opening hole,
wherein the mesh pattern is electrically connected to a corresponding one of the plurality of touch electrodes.

9. The display device of claim 6, comprising an auxiliary electrode disposed to overlap the second opening hole.

10. The display device of claim 9, further comprising a bridge electrode connecting the plurality of second touch electrodes,
wherein the auxiliary electrode is disposed on a same layer as the bridge electrode.

11. The display device of claim 10, further comprising:
a first touch insulating layer disposed on the encapsulation portion; and
a second touch insulating layer disposed on the bridge electrode and the auxiliary electrode,
wherein the bridge electrode electrically connects the plurality of second touch electrodes, and
wherein the auxiliary electrode is electrically connected to the touch electrode formed with the second opening hole by a through hole disposed in the second touch insulating layer.

12. The display device of claim 9, wherein the auxiliary electrode has a mesh shape.

13. The display device of claim 1, wherein a total area of the second opening hole in one of the plurality of touch electrodes is greater than or equal to a total area of the plurality of first opening holes in the one of the plurality of touch electrodes.

14. The display device of claim 1, wherein a shape of the second opening hole in one of the plurality of touch electrodes corresponds to a shape of the one of the plurality of touch electrodes.

15. The display device of claim 14, wherein the second opening hole in the one of the plurality of touch electrodes has a quadrangular shape, while the one of the plurality of touch electrodes has a quadrangular shape.

16. A display device comprising:
a plurality of pixels disposed on a substrate;
an encapsulation portion disposed on the plurality of pixels;
an auxiliary electrode disposed on the encapsulation portion;
a touch insulating layer disposed on the auxiliary electrode;
a plurality of touch electrodes disposed on the touch insulating layer; and
a black matrix disposed on the plurality of touch electrodes,
wherein the plurality of touch electrodes include a second opening hole exposing the auxiliary electrode.

17. The display device of claim 16, wherein the plurality of touch electrodes further include a plurality of first opening holes that expose each of the plurality of pixels, and
wherein a size of the second opening hole is larger than a size of each of the plurality of first opening holes.

18. The display device of claim 17, wherein the auxiliary electrode further includes a plurality of third opening holes that expose each of the plurality of pixels, and
wherein a size of each of the plurality of third opening holes are larger than the size of one of the plurality of first opening holes.

19. The display device of claim 17, wherein each of the plurality of first opening holes exposes one pixel among the plurality of pixels, and
wherein some of the plurality of first opening holes have different sizes from each other.

20. The display device of claim 16, wherein a shape of the second opening hole corresponds to a shape of the auxiliary electrode.
